(19) United States
(12) Patent Application Publication
(10) Pub. No.: US 2015/0140819 A1
(43) Pub. Date: May 21, 2015

(54) SEMICONDUCTOR PROCESS

(71) Applicant: UNITED MICROELECTRONICS CORP., Hsin-Chu City (TW)

(72) Inventors: Po-Cheng Huang, Kaohsiung City (TW); Yu-Ting Li, Chiayi City (TW); Chun-Hsiung Wang, Kaohsiung City (TW); Wu-Sian Sie, Tainan City (TW); Yi-Liang Liu, Tainan City (TW); Chia-Lin Hsu, Tainan City (TW); I-Ming Tseng, Kaohsiung City (TW)

(73) Assignee: UNITED MICROELECTRONICS CORP., Hsin-Chu City (TW)

(21) Appl. No.: 14/083,456

(22) Filed: Nov. 19, 2013

(51) Int. Cl. H01L 21/3105; H01L 21/762

(52) U.S. Cl. CPC H01L 21/31053; H01L 21/76224
USPC 438/692

(57) ABSTRACT

A semiconductor process includes the following steps. A substrate having trenches with different sizes is provided. A first oxide layer is formed to entirely cover the substrate. A prevention layer is formed on the first oxide layer. A first filling layer is formed on the prevention layer and fills the trenches until the first filling layer is higher than the substrate. A first polishing process is performed to polish the first filling layer until exposing the prevention layer. A second polishing process is performed to polish the first filling layer, the prevention layer and the first oxide layer until the substrate is exposed.

### BACKGROUND OF THE INVENTION

1. Field of the Invention

The present invention relates generally to a semiconductor process, and more specifically to a semiconductor process that applies chemical mechanical polishing (CMP) processes.

2. Description of the Prior Art

In the semiconductor industry, chemical mechanical polishing (CMP) is the most common and important planarization tool applied. Generally, the CMP process can be used to remove a topographical target of a thin film layer on a semiconductor wafer and to produce a wafer with both a regular and planar surface. In a CMP process, slurry is provided in a surface subject to planarization, and a mechanical polishing process is performed on the surface of the wafer. The slurry includes chemical agents and abrasives. The chemical agents may be PH buffers, oxidants, surfactants or the like, and the abrasives may be silica, alumina, zirconium oxide, or the like. The chemical reactions evoked by the chemical agents and the abrasion between the wafer, the abrasives, and the polishing pad can planarize the surface of the wafer.

CMP processes have been widely adopted in many aspects such as shallow trench isolation (STI) processes or copper (Cu) interconnection processes etc. For example, STI has advantages of a smaller isolation region and retaining planarization of the semiconductor substrate. STI structure is formed between two metal oxide semiconductor (MOS) transistors and surrounds an active region in the semiconductor substrate to prevent carriers, such as electrons or electric holes, from drifting between two adjacent devices through the substrate to cause junction current leakage. When CMP processes are applied in STI, they provide excellent and global planarization.

However, as layouts of integrated circuit devices become more complex and have high integration, it is difficult to maintain the quality of planarization in a large amount of regions with different properties, such as these regions include trenches with different sizes having STI filling therein.

### SUMMARY OF THE INVENTION

The present invention provides a semiconductor process to improve the planarization quality of CMP.

The present invention provides a semiconductor process including the following steps. A substrate having trenches with different sizes is provided. A first oxide layer is formed to entirely cover the substrate. A prevention layer is formed on the first oxide layer. A first filling layer is formed on the prevention layer and fills the trenches until the first filling layer is higher than the substrate. A first polishing process is performed to polish the first filling layer until the prevention layer is exposed. A second polishing process is performed to polish the first filling layer, the prevention layer and the first oxide layer until the substrate is exposed.

According to the above, the present invention provides a semiconductor process, which sequentially forms a first oxide layer, a prevent layer and a first filling layer on a substrate having trenches with different sizes; performs a first polishing process to polish the first filling layer until the prevention layer is exposed; then, performs a second polishing process to polish the first filling layer, the prevention layer and the first oxide layer until the substrate is exposed. By doing this, oxide layers filling in the trenches with different sizes have planarized top surfaces; that is, dishings on the oxide layers can be reduced or may not occur. The top part of the oxide layers will not be consumed while forming the oxide layers through performing polishing processes. Therefore, the semiconductor process of the present invention can improve the performances of a formed semiconductor structure such as an isolation structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 schematically depict cross-sectional views of a semiconductor process according to a first embodiment of the present invention.

FIGS. 5-8 schematically depict cross-sectional views of a semiconductor process according to a second embodiment of the present invention.

FIGS. 9-10 schematically depict cross-sectional views of a semiconductor process according to another embodiment of the present invention.

### DETAILED DESCRIPTION

FIGS. 1-4 schematically depict cross-sectional views of a semiconductor process according to a first embodiment of the present invention. As shown in FIG. 1, a substrate 110 is provided. The substrate 110 may include a bulk substrate 112 and a layer 114. The bulk substrate 112 may be a semiconductor substrate such as a silicon substrate, a silicon containing substrate, a III-V group-on-silicon (such as GaN-on-silicon) substrate, a graphene-on-silicon substrate or a silicon-on-insulator (SOI) substrate. The layer 114 may be a single layer or multi-layers according to the needs. In this embodiment, the layer 114 includes an oxide layer 114a and a nitride layer 114b from bottom to top; in another embodiment, the layer 114 may be an oxide layer or a nitride layer or similar.

More precisely, the substrate 110 has trenches R1, R2, R3 and the layer 114 covers the bulk substrate 112 other than the trenches R1, R2, R3. In this embodiment, the layer 114 serves as a hard mask for etching the bulk substrate 112 to form the trenches R1, R2, R3. The method for forming the trenches R1, R2, R3 includes the following step. A bulk substrate (not shown) is provided. A layer (not shown) is entirely formed and patterned on the bulk substrate, so that the layer 114 is formed on the bulk substrate. An etching process is performed to etch the bulk substrate, thereby the trenches R1, R2, R3 are formed. Therefore, the substrate 110 has trenches R1, R2, R3 and the layer 114 formed thereon other than the trenches R1, R2, R3 is formed. Then, a filling layer 120 entirely covers the substrate 110 and thus fills the trenches R1, R2, R3. In this embodiment the filling layer 120 is presented for an example; in another embodiment, there may be another material to cover the substrate 110, depending upon the needs. In this embodiment, the filling layer 120 may be formed through a chemical vapor deposition (CVD) process or a flowable chemical deposition process (FCVD) process and is for forming shallow trench isolation structures, which decides active areas having fin-shaped structures between them.

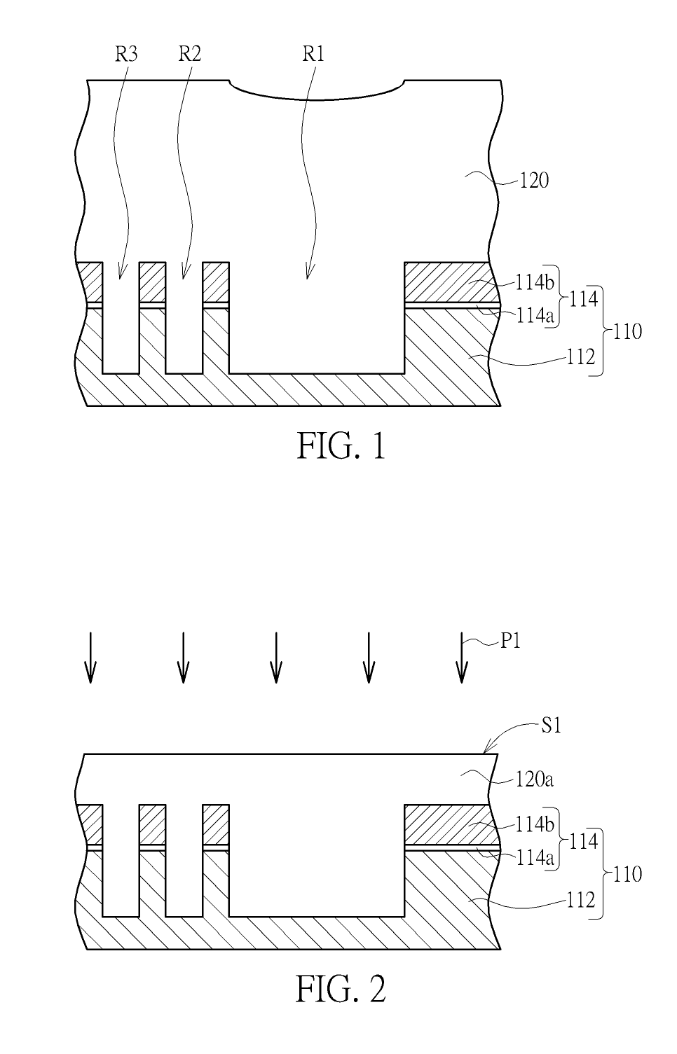

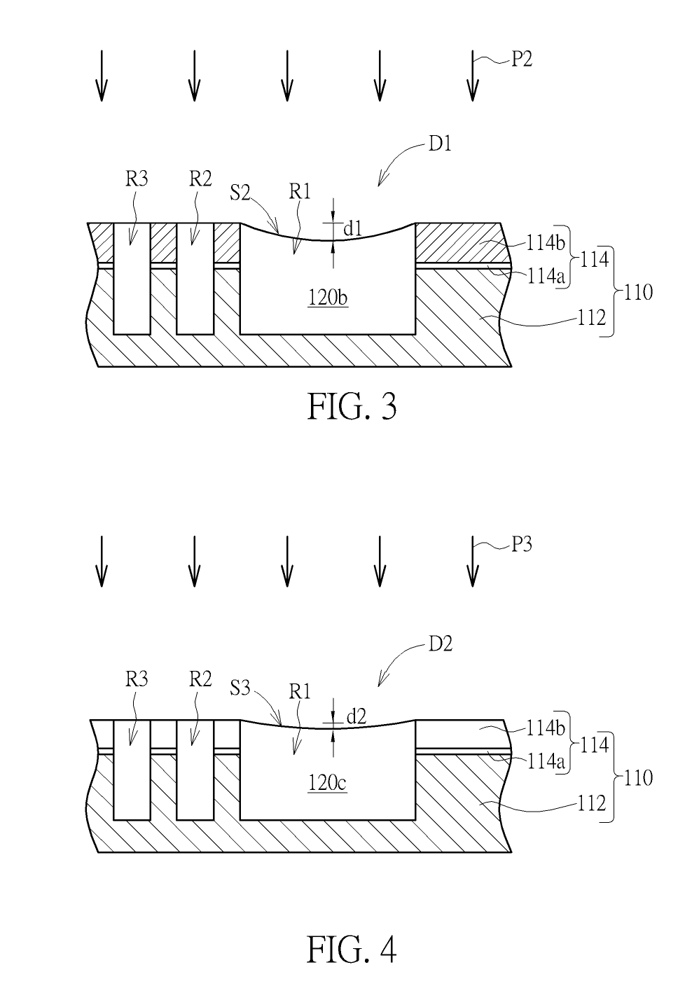

As shown in FIG. 2, a bulk polishing process P1 is performed to planarize the filling layer 120, thereby the filling layer, such as an oxide layer 120a having a planarized top surface S1 is formed. In this embodiment, the bulk polishing process P1 is a chemical mechanical polishing process, but it is not limited thereto. As shown in FIG. 3, a first polishing process P2 is performed to planarize the oxide layer 120a until the layer 114 is exposed, thereby the oxide layer 120b having a top surface S2 is formed.

In this embodiment, the first polishing process P2 is also a chemical mechanical polishing process and the etching rate of the first polishing process P2 to the oxide layer 120a is larger than that to the nitride layer 114b, so that the polishing can be stopped on the nitride layer 114b. Furthermore, the bulk polishing process P1 has a higher polishing rate for the first filling layer 120 than that of the first polishing process P2. Thus, the bulk polishing process P1 may remove a large amount of the oxide layer 120 firstly for saving processing time, and the first polishing process P2 is performed to achieve a precise predetermined thickness of the oxide layer 120b without over-etching by etching the oxide layer 120a with a slow etching rate.

However, since the trenches R1, R2, R3 have different sizes, that is, the trench R1 is larger than the trenches R2, R3, a dishing D1 occurs in the oxide layer 120b. Thus, sequential processes may be performed to remove the dishing D1 or at least decrease the depth dl of the dishing D1.

Therefore, as shown in FIG. 4, a second polishing process P3 is performed to remove the nitride layer 114b as well as the oxide layer 120b, thereby the oxide layer 120c having a top surface S3 flatter than the top surface S2 of the oxide layer 120b is formed. The etching rate of the second polishing process P3 for the oxide layer 120b is the same as that to the nitride layer 114 for planarizing the oxide layer 120b, thus the dishing D1 of the oxide layer 120b can be reduced and the depth d2 of the dishing D2 is smaller than the depth d1 of the dishing D1.

Accordingly, the dishing D1 caused by polishing the oxide layer 120a in the trenches R1, R2, R3 with different sizes can be reduced. However, the loss of the nitride layer 114b, is high, and the depth d3 of the oxide layer 120c is reduced, that would degrade a formed semiconductor structure. For instance, as the oxide layer 120c is applied to serve as an isolation structure, the performance degrades due to the lost and the shortening of the oxide layer 120c. Therefore, a second embodiment is provided as follows to solve the problem.

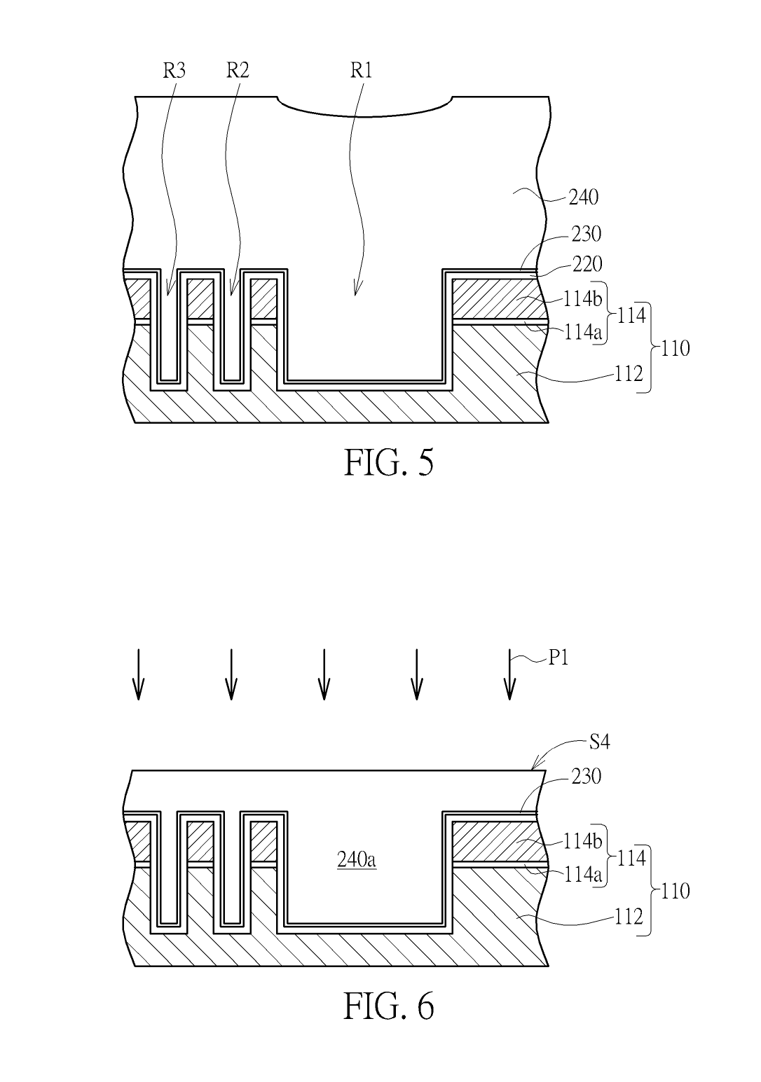

FIGS. 5-8 schematically depict cross-sectional views of a semiconductor process according to a second embodiment of the present invention. As shown in FIG. 5, a substrate 110 is provided. The substrate 110 may a bulk substrate 112 and a layer 114. The bulk substrate 112 may be a semiconductor substrate such as a silicon substrate, a silicon containing substrate, a III-V group-on-silicon (such as GaN-on-silicon) substrate, a graphene-on-silicon substrate or a silicon-on-insulator (SOI) substrate. The layer 114 may be a single layer or multi-layers according to the needs. In this embodiment, the layer 114 includes an oxide layer 114a and a nitride layer 114b from bottom to top; in another embodiment, the layer 114 may be an oxide layer or a nitride layer or similar.

More precisely, the substrate 110 has trenches R1, R2, R3 and the layer 114 covers the bulk substrate 112 other than the trenches R1, R2, R3. In this embodiment, the layer 114 serves as a hard mask for etching the bulk substrate 112 to form the trenches R1, R2, R3. The method for forming the trenches R1, R2, R3 is described in the first embodiment, and is not described again.

A first oxide layer 220 entirely covers the substrate 110 and thus fills the trenches R1, R2, R3. In a preferred embodiment, the first oxide layer 220 is performed by an atomic layer deposition (ALD) process for filling the recesses R1, R2, R3, especially for filling the recesses R2, R3 having smaller sizes.

Then, a prevention layer 230 is formed to cover the first oxide layer 220. The prevention layer 230 may be a silicon nitride layer, a silicon buffer film (SBF) or an amorphous silicon layer, but it is not limited thereto. The prevention layer 230 has material that can be transformed to be a similar material to the first oxide layer 220 through some processes. In some cases, the prevention layer 230 is formed by a deposition process or a modification process, but it is not limited thereto. In this embodiment, the modification process is a nitridation process, so that the prevention layer 230 is a silicon nitride layer.

Thereafter, a first filling layer 240 is formed on the prevention layer 230 and thus fills the trenches R1, R2, R3. In this embodiment, the first filling layer 240 is higher than the substrate 110 to form an isolation structure. In a preferred embodiment, the first filling layer 240 is formed by a chemical vapor deposition (CVD) process for saving processing time, but it is not limited thereto. Similarly, the first filling layer may also be formed through flowable chemical vapor deposition (FCVD) process.

In this embodiment, the first oxide layer 220 and the first filling layer 240 are presented for forming an isolation structure such as a shallow trench isolation structure; in another embodiment, there may be another material to cover the substrate 110 for forming another structure such as a metal interconnect structure or similar.

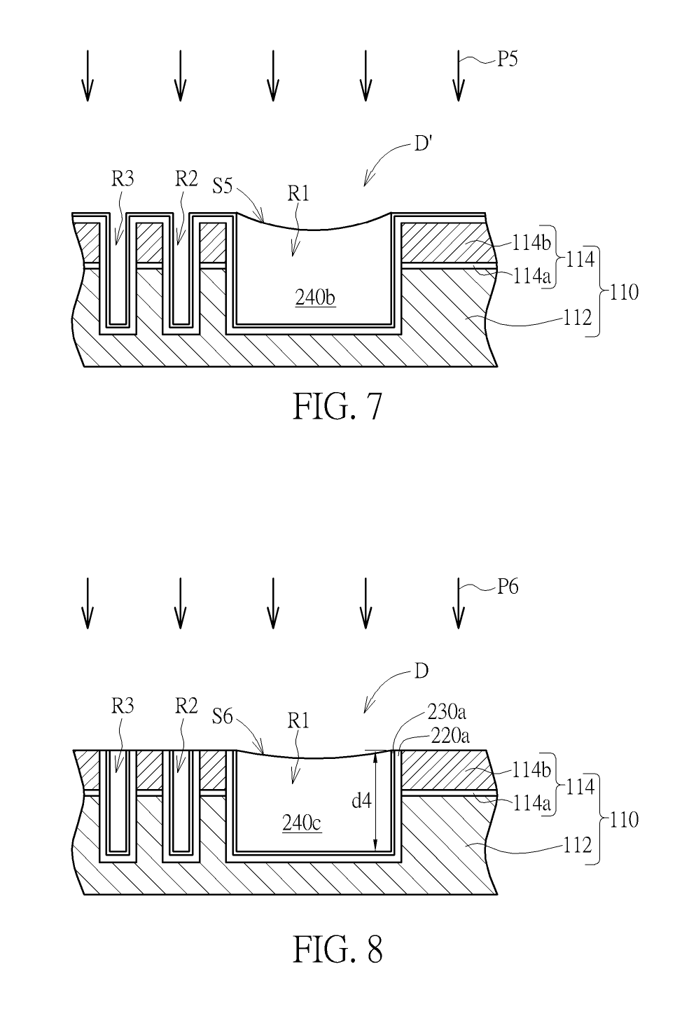

As shown in FIG. 6, a bulk polishing process P1 is performed to planarize the first filling layer 240, thereby the first filling layer 240a having a planarized top surface S4 is formed. In this embodiment, the bulk polishing process P1 is a chemical mechanical polishing process, but it is not limited thereto. As shown in FIG. 7, a first polishing process P5 is performed to planarize the first filling layer 240a until the prevention layer 230 is exposed, thereby the oxide layer 240b having a top surface S5 is formed.

In one case, the first polishing process P5 is also a chemical mechanical polishing process and the first polishing process P5 has different etching rates for the prevention layer 230 and the first filling layer 240a, enabling the polishing of the first polishing process P5 to stop on the prevention layer 230. In this embodiment, the first polishing process P5 has high selectivity slurry (HSS) and the polishing rate of the first polishing process P5 to the first filling layer 240a is higher than that of the prevention layer 230, so that the polishing can be stopped on the nitride layer 114b. Preferably, the polishing rate of the first polishing process P5 to the first filling layer 240a and to the prevention layer 230 has a ratio of 10:1.

Furthermore, the bulk polishing process P1 has a higher polishing rate for the first filling layer 240 than that of the first polishing process P5. Thus, the bulk polishing process P1 may remove a large amount of the first filling layer 240 firstly for saving processing time, and the first polishing process P5 is performed to achieve a precise predetermined thickness of the first filling layer 240b without over-polishing by polishing the first filling layer 240a with a slow polishing rate.

Then, a second polishing process P6 is performed to polish the first filling layer 240b, the prevention layer 230 and the first oxide layer 220 until the substrate 110 is exposed, as shown in FIG. 8. Therefore, the first filling layer 240c, the prevention layer 230a and the first oxide layer 220a are formed. In this embodiment, the second polishing process P6 has non selectivity slurry (NSS) and the second polishing process P6 has the same polishing rate for the prevention layer 230, the first oxide layer 220 and the first filling layer 240b, so that the first filling layer 240c has a top surface S6 flatter than the top surface S5 of the first filling layer 240b. Thus, the dishing D in the first filling layer 240c can be solved or can be at least smaller than the dishing D′ as shown in FIG. 7. It is emphasized that, the loss of the nitride layer 114b is substantially zero in this embodiment and the first filling layer 240c can be reserved to have an improved performance better than the oxide layer 120c of the first embodiment due to the depth d4 of the first filling layer 240c being larger than the depth d3 of the oxide layer 120c.

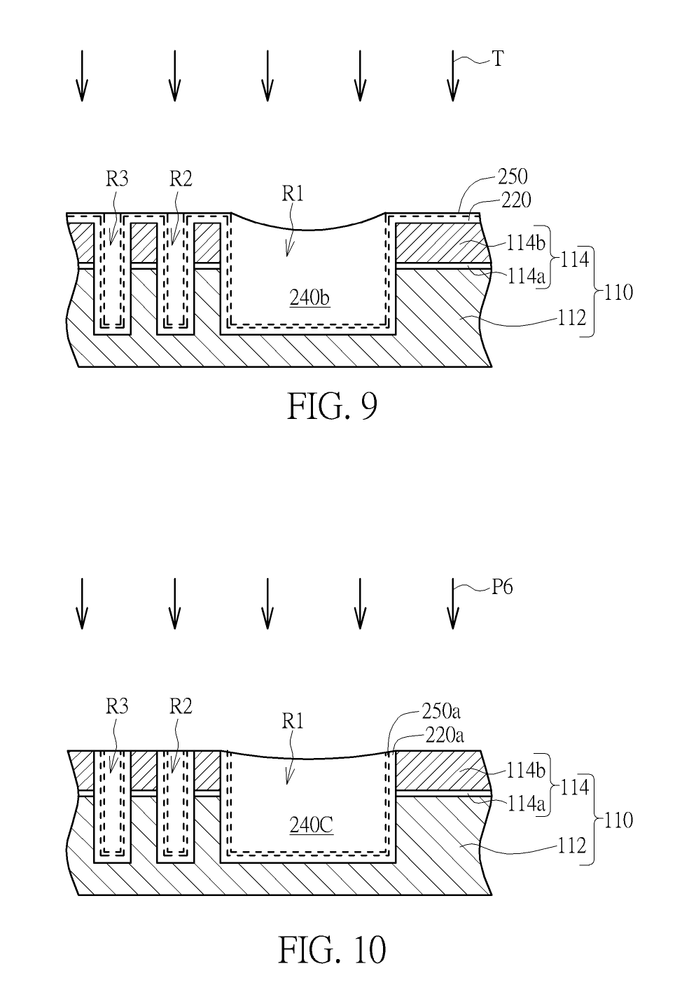

In another embodiment, a transformation process is performed to transform the prevention layer 230 or 230a to an oxide layer that is preferably similar to the first filling layer 240b and the first oxide layer 220. The transformation process is performed after the first polishing process P5 is performed; that is, the transformation process may be performed before or after the second polishing process P6 is performed. FIGS. 9-10 schematically depict cross-sectional views of a semiconductor process according to another embodiment of the present invention, which has the transformation process performed before the first filling layer 240b is polished.

After the first polishing process P5 is performed as shown in FIG. 7, a transformation process T is performed to transform the prevention layer 230 into an oxide layer 250, as shown in FIG. 9. The transformation process T is an annealing process in this embodiment, but it is not limited thereto. Preferably, the temperature of the annealing process is higher than 700° C.; still preferably, the temperature of the annealing process is higher than 1050° C., so that the prevention layer 230 can be fully transformed to the oxide layer 250. The material of the oxide layer 250 is similar to the first filling layer 240b and the first oxide layer 220. So, the oxide layer 250, the first filling layer 240b and the first oxide layer 220 have no polishing selectivity to a polishing process, and the quality of planarization can be improved. Besides, the prevention layer 230 will not remain in a finally formed semiconductor structure.

As shown in FIG. 10, the second polishing process P6 is performed to polish the first filling layer 240b, the oxide layer 250 and the first oxide layer 220 until the substrate 110 is exposed, and the first filling layer 240c, the oxide layer 250a and the first oxide layer 220a are therefore formed, wherein the first filling layer 240c, the oxide layer 250a and the first oxide layer 220a can be seen as a bulk oxide layer due to their similar or common materials. This means an isolation structure can be formed in this embodiment. In another embodiment, the bulk oxide layer can be applied to another structure. Besides, the bulk oxide layer is just one example. By applying the semiconductor process of the present application, the material of the bulk oxide layer can be replaced by metal or other materials to form other structures for different purposes.

To summarize, the present invention provides a semiconductor process, which sequentially forms a first oxide layer, a prevent layer and a first filling layer on a substrate having trenches with different sizes; performs a first polishing process to polish the first filling layer until the prevention layer is exposed; then, performs a second polishing process to polish the first filling layer, the prevention layer and the first oxide layer until the substrate is exposed. By doing this, oxide layers filling in the trenches with different sizes have planarized top surfaces; that is, dishings on the oxide layers can be reduced or may not occur. A layer such as a nitride layer (usually serving as a hard mask) on the substrate other than the trenches will not be consumed while forming the oxide layers through performing the polishing processes, and the top part of the oxide layers will not be consumed as well. Therefore, the semiconductor process of the present invention can improve the quality of performances of a formed semiconductor structure such as an isolation structure.

Moreover, the prevention layer may be formed by a deposition process or a modification process and the prevention layer may include a silicon nitride layer, a silicon buffer film (SBF) or an amorphous silicon layer, but it is not limited thereto. The polishing rate of the first polishing process to the first filling layer is higher than to the prevention layer. Thus, the polishing of the first polishing process can stop on the prevention layer without over-polishing. The polishing rate of the second polishing process to the prevention layer, the first oxide layer and the first filling layer is substantially the same, so that the oxide layers formed in the trenches can all have planarized top surfaces.

Furthermore, a transforming process may be performed after the first polishing process is performed to transform the prevention layer to an oxide layer. Since the oxide layer has similar properties to the first oxide layer and the first filling layer, the planarization quality of the second polishing process can be improved and the prevention layer will not remain in the finally formed semiconductor structure. The transforming process may be an annealing process. Preferably, the temperature of the annealing process is higher than 700° C. Still preferably, the temperature of the annealing process is higher than 1050° C. for fully transforming the prevention layer.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor process, comprising:
providing a substrate having trenches with different sizes;
forming a first oxide layer entirely covering the substrate including surfaces of the trenches;
forming a prevention layer comprising a silicon buffer film (SBF) on the first oxide layer;
forming a first filling layer being formed by a flowable chemical vapor deposition (FCVD) process directly on the prevention layer and filling the trenches until the first filling layer is higher than the substrate;
performing polishing process until the substrate is exposed.

2. The semiconductor process according to claim 1, wherein the first oxide layer is performed by an atomic layer deposition (ALD) process.

3. (canceled)

4. The semiconductor process according to claim 1, wherein the prevention layer is formed by a deposition process or a modification process.

5. The semiconductor process according to claim 4, wherein the modification process comprises a nitridation process.

6. (canceled)

7. The semiconductor process according to claim 1, wherein the first polishing process has different polishing rates for the prevention layer and the first filling layer, enabling the polishing of the first polishing process to stop on the prevention layer.

8. The semiconductor process according to claim 7, wherein the polishing rate of the first polishing process for the first filling layer is higher than for the prevention layer.

9. The semiconductor process according to claim 8, wherein the polishing rate of the first polishing process for the first filling layer and for the prevention layer has a ratio of 10:1.

10. The semiconductor process according to claim 1, wherein the second polishing process has the same polishing rate for the prevention layer, the first oxide layer and the first filling layer.

11. The semiconductor process according to claim 1, further comprising:
performing a bulk polishing process to polish the first filling layer before the first polishing process is performed.

12. The semiconductor process according to claim 11, wherein the bulk polishing process has a higher polishing rate for the first filling layer than that of the first polishing process.

13. The semiconductor process according to claim 1, further comprising:
performing a transforming process to transform the prevention layer to an oxide layer after the first polishing process is performed.

14. The semiconductor process according to claim 13, wherein the transforming process comprises an annealing process.

15. The semiconductor process according to claim 14, wherein the temperature of the annealing process is higher than 700° C.

16. The semiconductor process according to claim 15, wherein the temperature of the annealing process is higher than 1050° C.

17. The semiconductor process according to claim 1, wherein the substrate comprises a bulk substrate having the trenches and a layer covering the bulk substrate other than the trenches.

18. The semiconductor process according to claim 17, wherein the layer comprises an oxide layer or/and a nitride layer.

19. The semiconductor process according to claim 18, wherein the layer is a hard mask for etching the bulk substrate to form the trenches.

20. The semiconductor process according to claim 1, wherein the step of
performing the polishing process comprises:
performing a first polishing process to polish the first filling layer until exposing the prevention layer; and
performing a second polishing process to polish the first filling layer, the prevention layer and the first oxide layer until the substrate is exposed.
